(19) United States
(12) Patent Application Publication
(10) Pub. No.: US 2013/0240825 A1
(43) Pub. Date: Sep. 19, 2013

(54) NONVOLATILE VARIABLE RESISTANCE ELEMENT AND METHOD OF MANUFACTURING THE NONVOLATILE VARIABLE RESISTANCE ELEMENT

(71) Applicants: Shosuke Fujii, Kanagawa (JP); Daisuke Matsushita, Kanagawa (JP); Tomoya Kawai, Kanagawa (JP)

(72) Inventors: Shosuke Fujii, Kanagawa (JP); Daisuke Matsushita, Kanagawa (JP); Tomoya Kawai, Kanagawa (JP)

(73) Assignee: KABUSHIKI KAISHA TOSHIBA, Tokyo (JP)

(21) Appl. No.: 13/825,688

(22) PCT Filed: Feb. 28, 2011
(86) PCT No.: PCT/JP11/55162

§ 371 Date: May 16, 2013

(30) Foreign Application Priority Data
Oct. 14, 2010 (JP) 2010-231293

(51) Int. Cl. H01L 45/00

(52) U.S. Cl. CPC H01L 45/128
USPC 257/4; 438/382

(57) ABSTRACT

According to one embodiment, a first electrode, a second electrode, and a variable resistance layer are provided. The variable resistance layer is arranged between the first electrode and the second electrode and contains a polycrystalline semiconductor as a main component.

### CROSS-REFERENCE TO RELATED APPLICATIONS

This application is based upon and claims the benefit of priority from the prior Japanese Patent Application No. 2010-231293, filed on Oct. 14, 2010; the entire contents of which are incorporated herein by reference.

### FIELD

Embodiments disclosed herein relate generally to a nonvolatile variable resistance element and a method of manufacturing the nonvolatile variable resistance element.

### BACKGROUND

A NAND flash memory is widely spread as a storage device for large volume data. At present, a reduction in cost and an increase in capacity per bit are in progress by microminiaturizing a storage element. In future, it is requested to advance further miniaturization. However, to further miniaturize a flash memory, there are large number of problems that should be solved such as a short channel effect and suppression of cell-to-cell interference and performance fluctuation. Therefore, it is expected that a new storage device replacing a floating-gate type flash memory is put to practical use.

Recently, a two-terminal nonvolatile variable resistance element represented by a ReRAM (Resistive Random Access Memory) is actively developed. This element is a prospective candidate as a large-capacity storage device in the next generation replacing the floating gate flash memory in terms of the fact that a low-voltage operation, high-speed switching, and microminiaturization are possible. Above all, a memory including amorphous silicon as a variable resistance layer attracts attention because of a high switching yield and possibility of microminiaturization.

To realize a large-capacity storage device using such a two-terminal nonvolatile variable resistance element, in some case, a so-called stacked cross point structure is adopted. In this case, a thermal history applied to each of variable resistance elements during a manufacturing process for a storage device depends on in which layer the variable resistance element is present. Therefore, when the variable resistance element has relatively weak thermal resistance, it is likely that a characteristic of the element changes according to the thermal history. This causes characteristic fluctuation in the element.

In particular, when amorphous silicon is used as a variable resistance film, it is feared that a phase change from an amorphous structure to a polycrystalline structure is caused depending on a thermal history. An element characteristic substantially changes because of a volume change and a conductivity change involved in the phase change.

Patent Document 1 US2010/0085798

### BRIEF DESCRIPTION OF DRAWINGS

FIG. 1 is a sectional view of a schematic configuration of a nonvolatile variable resistance element according to a first embodiment;

FIG. 2 is a transmission electron microscope image obtained when polysilicon is used as a variable resistance layer 3 shown in FIG. 1;

FIG. 3A is a sectional view of a low-resistance state of the nonvolatile variable resistance element shown in FIG. 1;

FIG. 3B is a sectional view of a high-resistance state of the nonvolatile variable resistance element shown in FIG. 1;

FIG. 4 is a graph of a switching characteristic of the nonvolatile variable resistance element shown in FIG. 1;

FIG. 5 is a graph of secondary ion mass spectrometry results obtained when a hydrogen content of the variable resistance layer 3 shown in FIG. 1 is small and when the hydrogen content is large;

FIG. 6 is a sectional view of a schematic configuration of a nonvolatile variable resistance element according to a third embodiment;

FIG. 7 is a schematic diagram of a path for the metal to form a filament when hydrogen contents of variable resistance layer 3 or 3′ shown in FIG. 1 or 6 is small;

FIG. 8 is a schematic diagram of a path for the metal to form a filament when the hydrogen contents of the variable resistance layer 3 or 3′ shown in FIG. 1 or 6 is large;

FIG. 9A is a graph of a comparison of voltage current characteristics obtained when a hydrogen content of the variable resistance layer 3 shown in FIG. 1 is small and when the hydrogen content is large;

FIG. 9B is a diagram for explaining a method of measuring the voltage current characteristics;

FIG. 10 is a schematic diagram of a flow of metal ion flowing when the variable resistance layers 3 or 3′ shown in FIG. 1 or 6 transitions from a high-resistance state to a low-resistance state;

FIG. 11 is a schematic diagram of a flow of metal ion flowing when the variable resistance layers 3 or 3′ shown in FIG. 1 or 6 transition from the low-resistance state to the high-resistance state;

FIG. 12A is a plan view of a schematic configuration of a memory cell array to which a nonvolatile variable resistance element according to a fifth embodiment is applied;

FIG. 12B is a sectional view of a schematic configuration of a cross-point section of the memory cell array shown in FIG. 12A;

FIG. 13 is a sectional view of a schematic configuration of a nonvolatile variable resistance element according to a sixth embodiment;

FIG. 14 is a plan view of a schematic configuration of a memory cell array to which the nonvolatile variable resistance element shown in FIG. 13 is applied;

FIG. 15 is a sectional view of a schematic configuration of a nonvolatile variable resistance element according to a seventh embodiment; and

FIG. 16 is a plan view of a schematic configuration of a memory cell array to which the nonvolatile variable resistance element shown in FIG. 15 is applied.

### DETAILED DESCRIPTION

In general, according to one embodiment, a first electrode, a second electrode, and a variable resistance layer are provided. The variable resistance layer is arranged between the first electrode and the second electrode and contains a polycrystalline semiconductor as a main component.

Exemplary embodiments of nonvolatile variable resistance elements and methods of manufacturing the nonvolatile variable resistance elements will be explained below in detail with reference to the accompanying drawings. The present invention is not limited to the following embodiments.

### First Embodiment

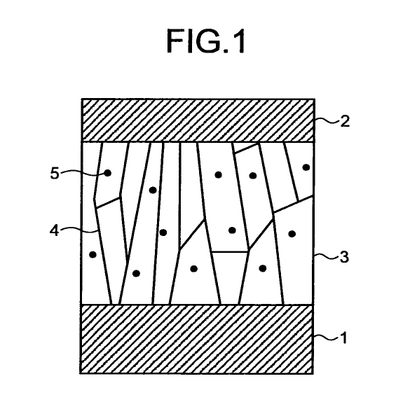

FIG. 1 is a sectional view of a schematic configuration of a nonvolatile variable resistance element according to a first embodiment.

In FIG. 1, in this nonvolatile variable resistance element, a variable resistance layer 3 is stacked on a first electrode 1 and a second electrode 2 is stacked on the variable resistance layer 3. A main component of the variable resistance layer 3 is a polycrystalline semiconductor. Grain boundaries 4 are formed in the variable resistance layer 3. As a material of this semiconductor, for example, Si, Ge, SiGe, GaAs, InP, GaP, GaInAsP, GaN, or SiC can be used. Hydrogen 5 is added in the variable resistance layer 3. The concentration of hydrogen contained in the polycrystalline semiconductor is equal to or higher than 10¹⁹ cm⁻³.

When the polycrystalline semiconductor of the variable resistance layer 3 is polysilicon, impurity-doped silicon can be used as the first electrode 1. For example, high-concentration B ion can be implanted in silicon such that the resistivity of the first electrode 1 is equal to or lower than 0.005 Ωcm. The second electrode 2 is an electrode containing metal. For example, Ag can be used as the second electrode 2. Other conductive materials can be used as the first electrode 1 and the second electrode 2. For example, Ag, Au, Ti, Ni, Co, Al, Fe, Cr, Cu, W, Hf, Ta, Pt, Ru, Zr, or Ir, or nitride or carbide of the metal, or the like can be used as the first electrode 1 and the second electrode 2. An alloy material containing a plurality of kinds among these metals and semiconductor elements can also be used as the first electrode 1 and the second electrode 2. The first electrode 1 and the second electrode 2 can contain the same metal.

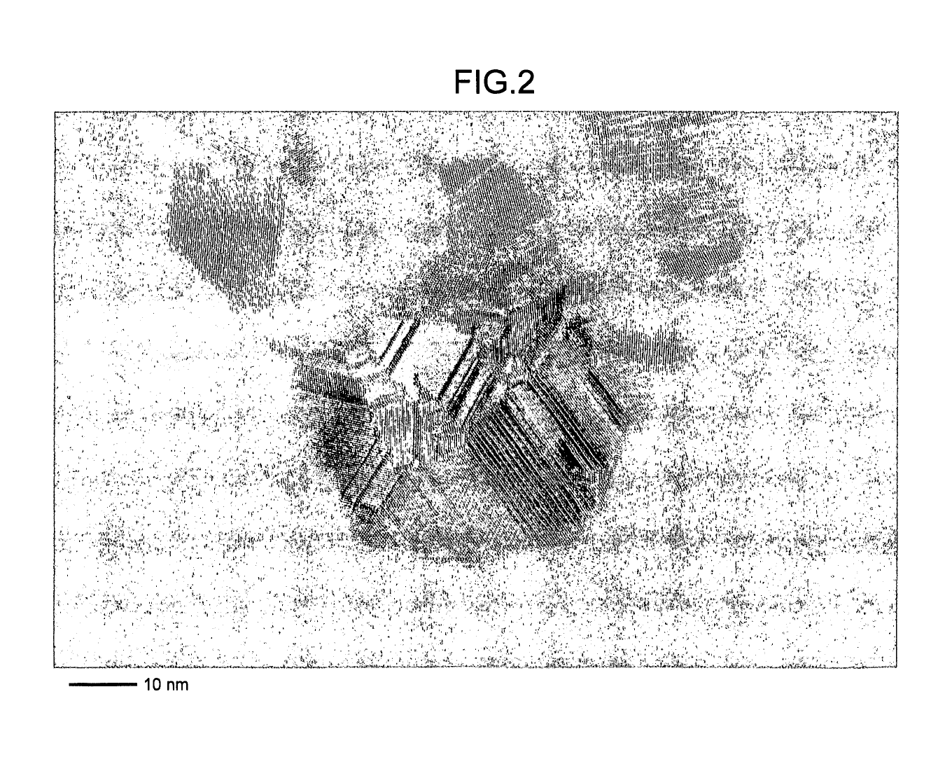

FIG. 2 is a diagram of a transmission electron microscope image obtained when polysilicon is used as the variable resistance layer 3 shown in FIG. 1.

In FIG. 2, crystal grains having a diameter of about 10 nanometers are seen in this variable resistance layer 2. A grain diameter of this polysilicon does not always need to be 10 nanometers. To realize a large-capacity storage device, microminiaturization of a nonvolatile variable resistance element is necessary. Therefore, it is more desirable that the grain diameter of the polysilicon is also smaller. Typically, the grain diameter of the polysilicon is 2 nanometers to 10 nanometers. From the viewpoint of suppressing performance variability in the nonvolatile variable resistance element involved in the microminiaturization, it is more desirable that the grain diameter of the polysilicon is 2 nanometers to 5 nanometers. The grain diameter of the polysilicon can be controlled according to temperature and a flow rate of a material gas during film formation.

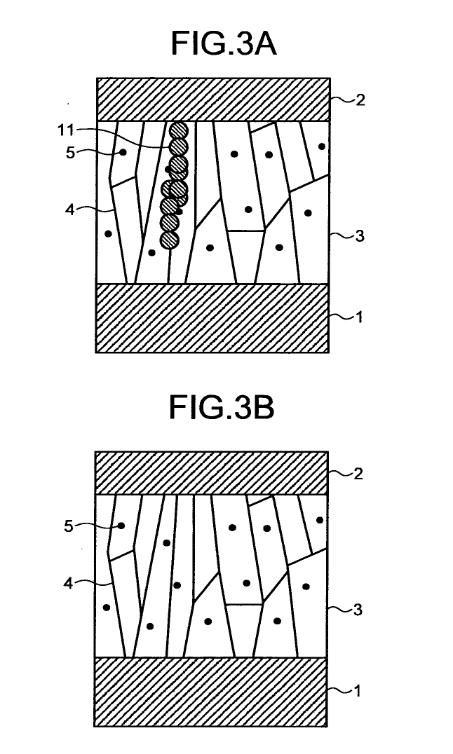

FIG. 3A is a sectional view of a low-resistance state of the nonvolatile variable resistance element shown in FIG. 1. FIG. 3B is a sectional view of a high-resistance state of the nonvolatile variable resistance element shown in FIG. 1.

In FIGS. 3A and 3B, the variable resistance layer 3 changes from a high-resistance state to a low-resistance state when metal filaments 11 become bigger along grain boundaries of the polycrystalline semiconductor, and changes from the low-resistance state to the high-resistance state when the metal filaments 11 formed along the grain boundaries of the polycrystalline semiconductor become smaller.

For example, in the low-resistance state, the metal of the second electrode 2 intrudes into the variable resistance layer 3 and forms metal filaments 11. On the other hand, in the high-resistance state, the metal filaments 11 that intrude into the variable resistance layer 3 are collected by the second electrode 2. The metal filaments 11 formed in the variable resistance layer 3 are eliminated. The nonvolatile variable resistance element can store data for one bit by reversibly transitioning between these two states according to voltage application.

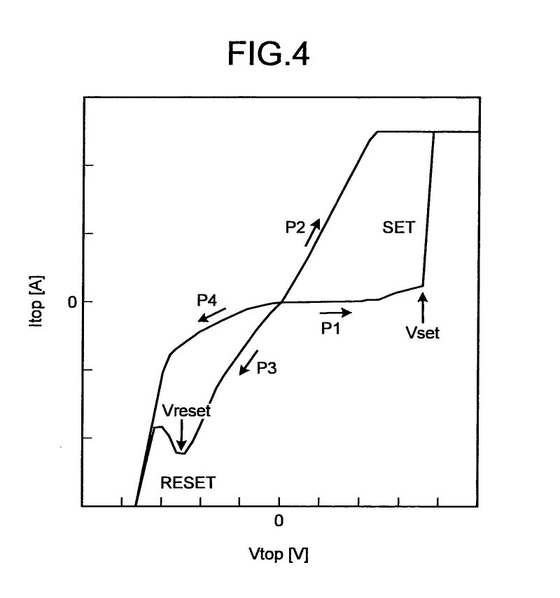

FIG. 4 is a graph of a switching characteristic of the nonvolatile variable resistance element shown in FIG. 1.

In FIG. 4, when a voltage Vtop applied to the second electrode 2 of the nonvolatile variable resistance element is increased in a positive direction (P1), an electric current Itop suddenly increases at a set voltage Vset (near 4 volts) and the nonvolatile variable resistance element transitions from the high-resistance state to the low-resistance state.

In the low-resistance state, in a range in which the voltage Vtop is smaller than the set voltage Vset to some degree, the electric current Itop flows generally in proportion to the voltage Vtop (P2).

On the other hand, when the voltage Vtop is swept in a negative direction with respect to the nonvolatile variable resistance element in the low-resistance state, the electric current Itop suddenly decreases at a reset voltage Vreset (near −2.5 volts) and the nonvolatile variable resistance element transitions from the low-resistance state to the high-resistance state (P3).

In the high-resistance state, in a range in which the voltage Vtop is larger than the reset voltage Vreset to some degree, the electric current Itop hardly flows with respect to the voltage Vtop (P4).

When the voltage Vtop is further swept in the positive direction from this state (P1), the electric current Itop suddenly increases at the set voltage Vset and the nonvolatile variable resistance element transitions from the high-resistance state to the low-resistance state. In other words, this nonvolatile variable resistance element can store data for one bit by reversibly transitioning between the high-resistance state and the low-resistance state.

### Second Embodiment

A method of manufacturing the nonvolatile variable resistance element shown in FIG. 1 is explained.

In FIG. 1, B ion is implanted in a silicon single crystal substrate, for example, at an acceleration voltage of 30 keV and dosage of 2×10¹⁵ cm⁻². Thereafter, activation anneal is applied to the silicon single crystal substrate, whereby the first electrode 1 is formed.

Subsequently, polysilicon is deposited on the first electrode 1 by, for example, a chemical vapor deposition (CVD) method, whereby the variable resistance film 3 is formed on the first electrode 1. Film formation conditions for the polysilicon are set such that the concentration of hydrogen contained in the polysilicon is equal to or higher than 10¹⁹ cm⁻³.

For example, as film formation conditions by an LP-CVD (Low Pressure Chemical Vapor Deposition) method, a material gas is SiH₄ and a flow rate and pressure can be respectively set to 100 sccm and 0.1 Torr. Film formation temperature can be set to 620° C. In the case of such film formation conditions, deposition speed of the polysilicon is 9 nm/min.

When silane gas SiH₄ or disilane gas Si₂H₆ alone is used as the material gas during film formation, to keep the concentration of hydrogen contained in the polysilicon layer at concentration equal to or higher than 10¹⁹ cm⁻³, it is desirable that hydrogen present in the material gas does not remove during the film formation. Therefore, it is necessary to set the deposition speed as high as possible. For example, when temperature during the film formation is 620° C. and the film formation is performed at deposition speed equal to or higher than 9 nm/min, the hydrogen concentration can be kept at concentration equal to or higher than 10¹⁹ cm⁻³. In the case of this embodiment, the film thickness of the variable resistance layer is 150 nanometers. The film thickness of the variable resistance layer does not need to be 150 nanometers. Typically, the film thickness of the variable resistance layer is 1 nanometer to 300 nanometers. If microminiaturization of an element is taken into account, the film thickness is desirably smaller. However, if the film thickness is too small, a uniform film is not obtained. Therefore, the film thickness is more desirably 2 nanometers to 50 nanometers.

The temperature during the film formation does not always need to be 620° C. To deposit polysilicon containing hydrogen at concentration equal to or higher than 10¹⁹ cm⁻³, typically, it is desirable to set the film formation temperature to 600° C. to 700° C. and set the deposition speed to speed equal to or higher than 9 nm/min.

It is unnecessary to use silane or disilane alone as the material gas. Mixed gas of silane or disilane and hydrogen can be used as a material. In this case, as in the above case, the concentration of hydrogen contained in the polysilicon can be kept at concentration equal to or higher than 10¹⁹ cm⁻³.

A metal film is formed on the polysilicon film by a method such as sputtering or vapor deposition, whereby the second electrode 2 is formed on the variable resistance layer 3.

In the embodiment explained above, a method of depositing the polysilicon layer on the first electrode 1 at the film formation temperature equal to or higher than 600° C. is explained. However, after an amorphous silicon layer is formed on the first electrode 1 at film formation temperature lower than 600° C., the amorphous silicon layer can be changed to a polycrystalline semiconductor layer by subjecting the amorphous silicon layer to thermal treatment at temperature equal to or higher than 600° C.

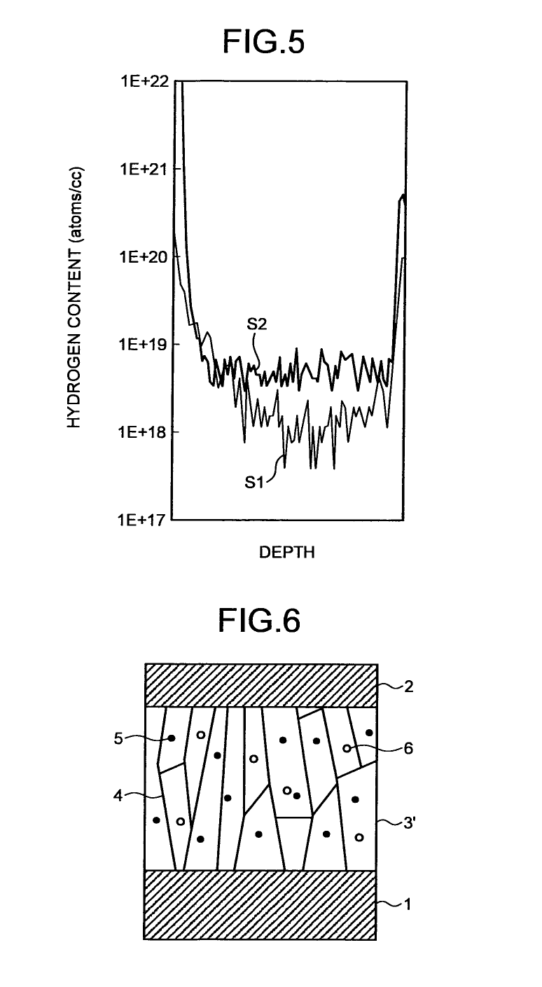

FIG. 5 is a graph of secondary ion mass spectrometry results obtained when a hydrogen content of the variable resistance layer 3 shown in FIG. 1 is small and when the hydrogen content is large. “Depth” on the abscissa in the figure is depth from a surface of each sample in contact with the second electrode 2.

In FIG. 5, in a sample S1 in which the concentration of hydrogen contained in polysilicon was lower than 10¹⁹ cm⁻³, the switching characteristic shown in FIG. 4 was not obtained. In a sample S2 in which the concentration of hydrogen contained in polysilicon was equal to or higher than 10¹⁹ cm⁻³, the switching characteristic shown in FIG. 4 was obtained. As the content of hydrogen contained in the polysilicon, a median or a mode in a depth direction of the variable resistance layer 3 can be used.

### Third Embodiment

FIG. 6 is a sectional view of a schematic configuration of a nonvolatile variable resistance element according to a third embodiment.

In FIG. 6, in this nonvolatile variable resistance element, a variable resistance layer 3′ is provided instead of the variable resistance layer 3 shown in FIG. 1. In this variable resistance layer 3′, oxygen 6 is added in a polycrystalline semiconductor.

It is possible to further improve thermal resistance of the nonvolatile variable resistance element by adding a very small amount of oxygen in the polycrystalline semiconductor. In particular, when impurity doped silicon is used as the first electrode 1, it is possible to suppress impurities from diffusing in the variable resistance layer 3′ and further improve reliability of a large-capacity storage device. According to the examination of the inventors, it is known that a thermal resistance improvement effect is obtained by adding oxygen by an amount equal to or larger than 10²¹ atoms/cm³.

### Fourth Embodiment

A method of manufacturing the nonvolatile variable resistance element shown in FIG. 6 is explained.

In FIG. 6, the variable resistance layer 3′ is formed on the first electrode 1 by forming a polysilicon layer by, for example, an LP-CVD (Low Pressure Chemical Vapor Deposition) method. When the variable resistance layer 3′ is formed, mixed gas of SiH4 and oxygen can be used as a material gas. The concentration of oxygen contained in the polysilicon can be controlled by changing a ratio of flow rates of silane gas and oxygen.

In this example, oxygen is used for the material gas. However, oxygen does not always need to be used for the material gas. NO gas or N2O gas can be mixed with silane gas. Because the variable resistance layer 3′ is deposited at deposition speed of 9 nm/min, a hydrogen content is equal to or larger than 10¹⁹ cm⁻³.

It is possible to suppress a grain diameter of the polysilicon by controlling the ratio of flow rates of silane gas and oxygen during film formation. To realize a large-capacity storage device, because microminiaturization of the nonvolatile variable resistance element is necessary, it is desirable that the grain diameter of the polysilicon is also smaller. Typically, the grain diameter of the polysilicon is 2 nanometers to 10 nanometers. From the viewpoint of suppressing characteristic fluctuation in the nonvolatile variable resistance element involved in the microminiaturization, it is more desirable that the grain diameter of the polysilicon is 2 nanometers to 5 nanometers. The grain diameter of the polysilicon indicates a maximum of crystal grains measured by Atom Probe.

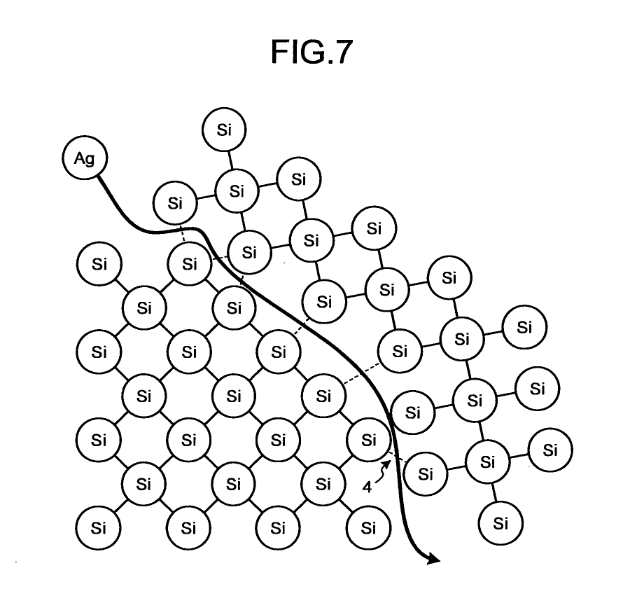

FIG. 7 is a schematic diagram of a path for the metal to form a filament when the hydrogen contents of the variable resistance layer 3 or 3′ shown in FIG. 1 or 6 is small. In an example explained below, the first electrode 1 is formed of Ag.

In FIG. 7, because the silicon atoms inside a crystal phase are densely bonded, gaps into which the metal Ag supplied from the first electrode intrudes are extremely small. Activation energy necessary for movement of the metal Ag is high. Therefore, the metal filaments 11 are formed mainly along the grain boundaries 4.

When a hydrogen content of the polysilicon is small, the gaps are small even in the grain boundaries 4 and the activation energy necessary for movement of the metal Ag is large. Therefore, the metal filaments 11 are less easily formed in the variable resistance layers 3 or 3′.

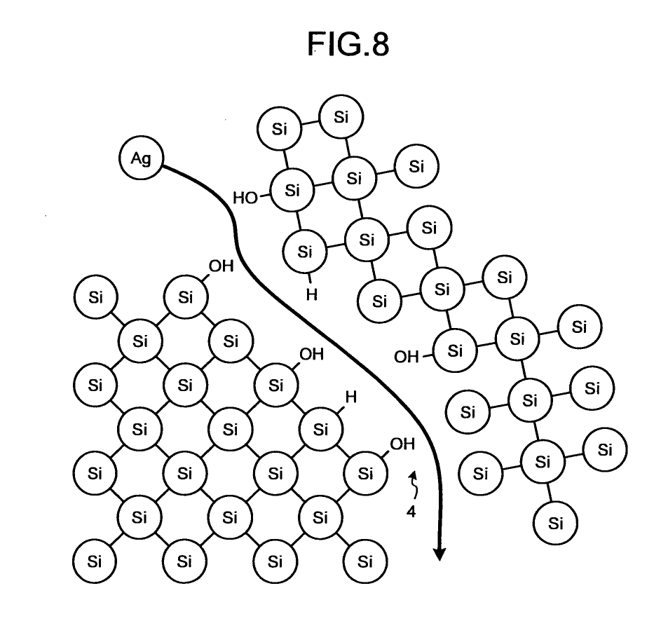

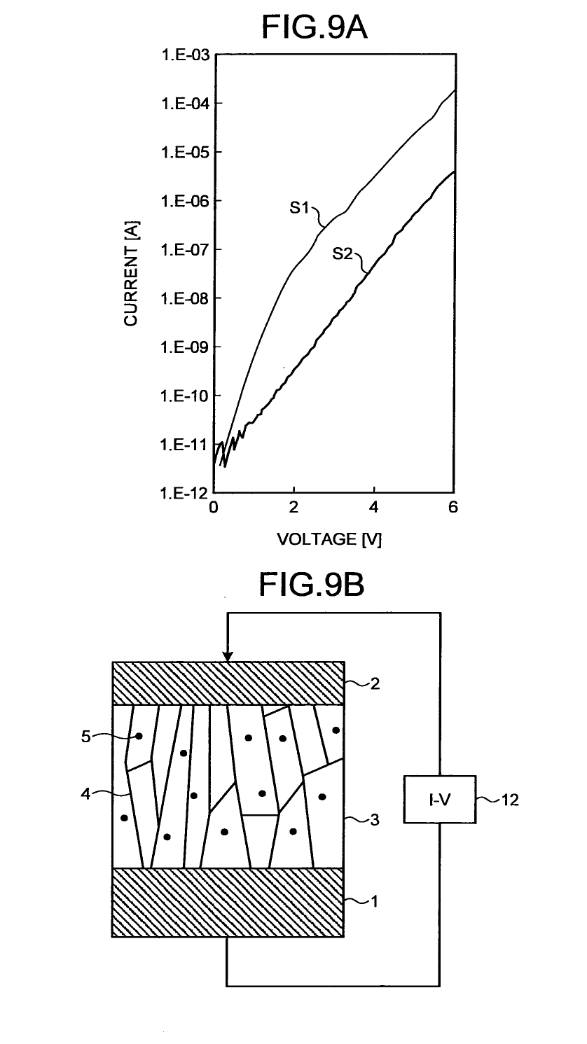

FIG. 8 is a schematic diagram of a path for the metal to form a filament when the hydrogen contents of the variable resistance layer 3 or 3′ shown in FIG. 1 or 6 is large.

In FIG. 8, when a hydrogen content of polysilicon is large, because the silicon atoms are bonded in a crystal phase, hydrogen is present in the grain boundaries 4 by forming Si—H bond or Si—OH bond. Therefore, distances among Si atoms in grain boundaries are structurally expanded and the metal Ag supplied from the first electrode 1 easily intrudes into gaps. As a result, the metal filaments 11 are easily formed in the variable resistance layers 3 and 3′.

FIG. 9A is a graph of a comparison of voltage current characteristics obtained when a hydrogen content of the variable resistance layer 3 shown in FIG. 1 is small and when the hydrogen content is large. FIG. 9B is a diagram for explaining a method of measuring the voltage current characteristics.

In FIG. 9B, the voltage current characteristic of the variable resistance layer 3 is measured by connecting the first electrode 1 and the second electrode 2 via an ammeter 12.

As a result, as shown in FIG. 9A, a current amount is large in the sample S1 in which the concentration of hydrogen contained in the polysilicon is lower than 10¹⁹ cm⁻³ compared with the sample S2 in which the concentration of hydrogen contained in the polysilicon is equal to or higher than 10¹⁹ cm⁻³.

In the case of the polysilicon, electrons move by hopping in the grain boundaries 4. Therefore, when an electric current is large, this indicates that the electrons easily hop in the grain boundaries 4 and the gaps present in the grain boundaries 4 are small. It is seen that, when hydrogen in the polysilicon increases, a current flowing through the polysilicon decreases and the electrons less easily hop in the grain boundaries 4.

Further, when OH groups are present in grain boundaries into which a metal element intrudes, metal ion is easily formed by a reaction described below.

Ag+OH→Ag(OH)→Ag⁺+OH⁻

When metal that forms the metal filament 11 is easily ionized through the above described reaction, this substantially contributes to improvement of the switching characteristic. Since elimination and generation of the metal filaments 11 composed of the metal element is controlled by applying voltage, it is desirable that the metal element is ionized. When a large number of OH groups are present in a moving path of the metal element, the metal element is easily ionized.

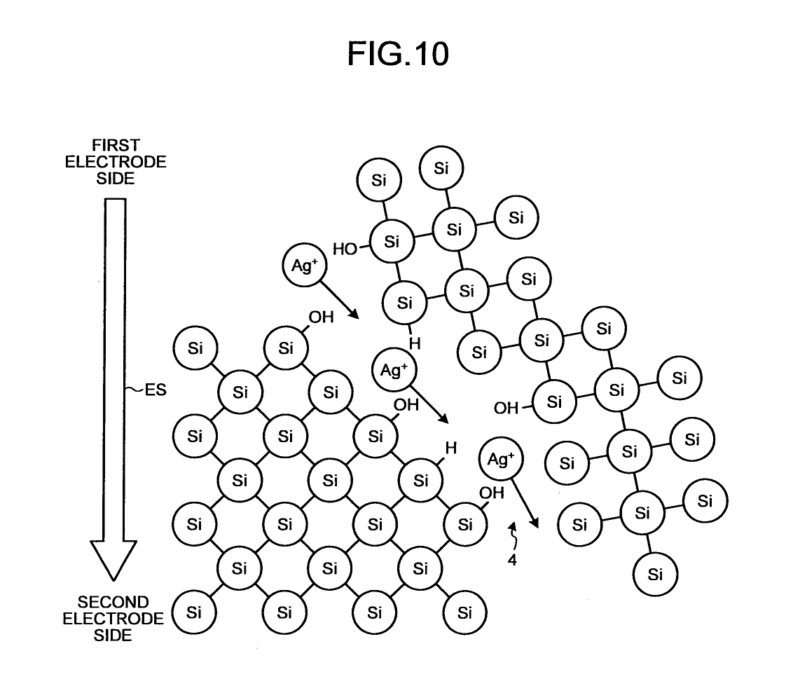

FIG. 10 is a schematic diagram of a flow of metal ion flowing when the variable resistance layers 3 or 3′ shown in FIG. 1 or 6 transition from a high-resistance state to a low-resistance state.

In FIG. 10, an electric field for set operation ES is applied to the variable resistance layers 3 or 3′, whereby the metal element moves to form the metal filaments 11.

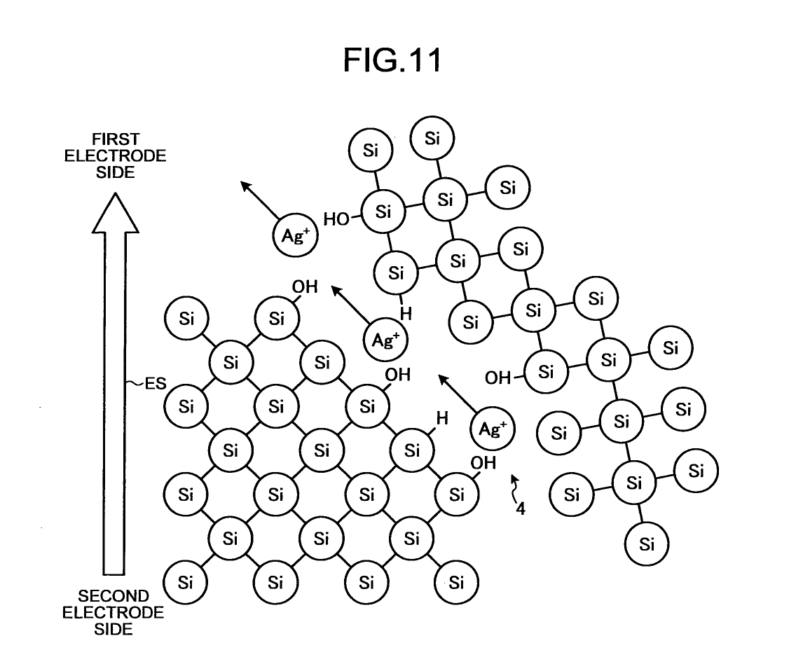

FIG. 11 is a schematic diagram of a flow of metal ion flowing when the variable resistance layer 3 or 3′ shown in FIG. 1 or 6 transitions from the low-resistance state to the high-resistance state.

In FIG. 11, an electric field for reset operation ER is applied to the variable resistance layers 3 or 3′, whereby the metal element moves to eliminate the metal filaments 11. With such a mechanism, it is possible to realize a nonvolatile storage element in which the variable resistance layers 3 or 3′ is composed of polysilicon.

### Fifth Embodiment

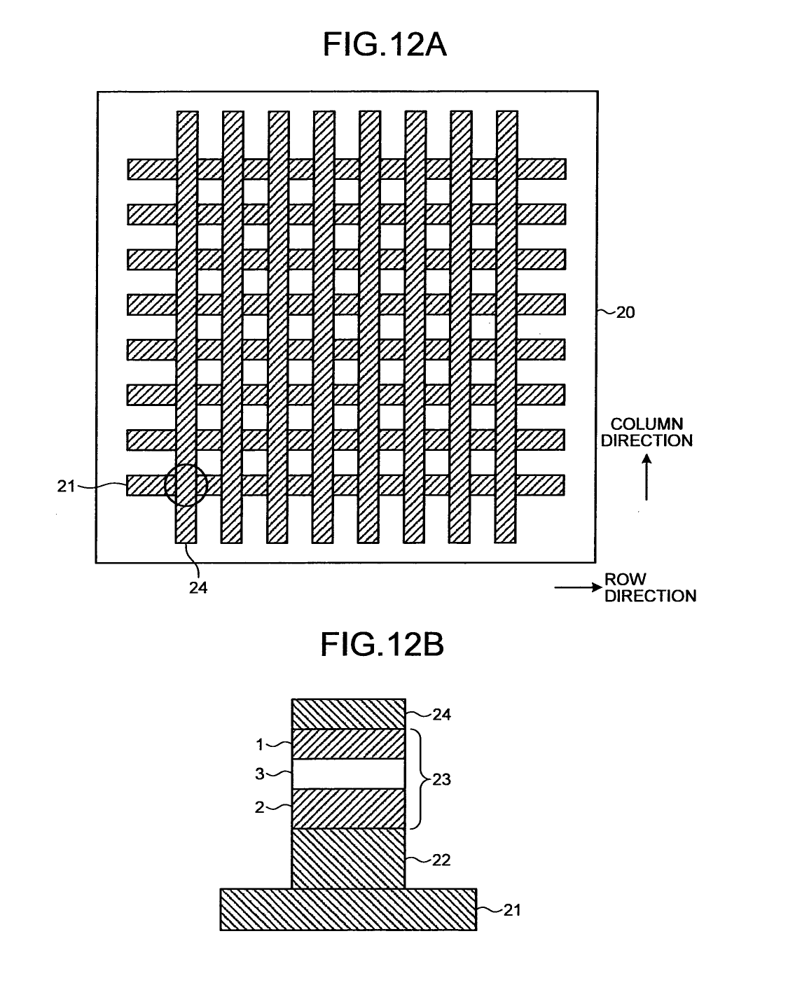

FIG. 12A is a plan view of a schematic configuration of a memory cell array to which a nonvolatile variable resistance element according to a fifth embodiment is applied. FIG. 12B is a sectional view of a schematic configuration of a cross-point section of the memory cell array shown in FIG. 12A.

In FIG. 12A, on a semiconductor chip 20, lower wires 21 are formed in a row direction and upper wires 24 are formed in a column direction. A memory cell 23 is arranged between the lower wires 21 and the upper wires 24 via a rectifying element 22. In some case, the rectifying element 22 is omitted. In this case, the height of the memory cell array (in a vertical direction on the paper surface in FIG. 12A) can be reduced and the nonvolatile variable resistance element can be easily fabricated.

As the memory cell 23, for example, the nonvolatile variable resistance element shown in FIG. 1 can be used. The variable resistance layer 3 can be stacked on the second electrode 2. The first electrode 1 can be stacked on the variable resistance layer 3. As the memory cell 23, the nonvolatile variable resistance element shown in FIG. 6 can be used.

When writing in a selected cell is performed, the set voltage Vset is applied to the lower wire 21 of a selected column and a ½ voltage of the set voltage Vset is applied to the lower wire 21 of unselected columns. 0 V is applied to the upper wire 24 of a selected row. The ½ voltage of the set voltage Vset is applied to the upper wire 24 of unselected rows.

As a result, the set voltage Vset is applied to the selected cell designated by the selected row and the selected column and writing in the selected cell is performed. On the other hand, because the ½ voltage of the set voltage Vset is applied to a half-selected cells designated by the unselected columns and the selected row, writing in the half-selected cells is not performed. Because, the ½ voltage of the set voltage Vset is applied to a half-selected cells designated by the selected column and the unselected rows, writing in the half-selected cells is not performed. Because 0 V is applied to an unselected cells designated by the unselected rows and the unselected columns, writing in the unselected cells is not performed. Therefore, it is possible to apply Vset only to the selected cell and perform writing in the selected cell.

When read out from the selected cell is performed, a ½ voltage of a read voltage Vread is applied to the lower wire 21 of the selected column and 0 V is applied to the lower wire 21 of the unselected columns. A −½ voltage of the read voltage Vread is applied to the upper wire 24 of the selected row and 0 V is applied the upper wire 24 of the unselected rows.

As a result, the read voltage Vread is applied to the selected cell designated by the selected row and the selected column and readout from the selected cell is performed. On the other hand, because the −½ voltage of the read voltage Vread is applied to the half-selected cells designated by the unselected columns and the selected row, readout from the half-selected cells is not performed. Because the ½ voltage of the read voltage Vread is applied to the half-selected cells designated by the selected column and the unselected rows, readout from the half-selected cells is not performed. Because 0 V is applied to the unselected cells designated by the unselected rows and the unselected columns, readout from the unselected cells is not performed.

When erasing in the selected cell is performed, the reset voltage Vreset is applied to the lower wire 21 of the selected column and a ½ voltage of the reset voltage Vreset is applied to the lower wiring 21 of the unselected columns. 0 V is applied to the upper wire 24 of the selected row and the ½ voltage of the reset voltage Vreset is applied to the upper wire 24 of the unselected rows.

As a result, the reset voltage Vreset is applied to the selected cell designated by the selected row and the selected column and erasing in the selected cell is performed. On the other hand, because the ½ voltage of the reset voltage Vreset is applied to the half-selected cells designated by the unselected columns and the selected rows, erasing in the half-selected cells is not performed. Because the ½ voltage of the reset voltage Vreset is applied to the half-selected cells designated by the selected column and the unselected rows, erasing in the half-selected cells is not performed. Because 0 V is applied to the unselected cells designated by the unselected rows and the unselected columns, erasing in the unselected cells is not performed.

### Sixth Embodiment

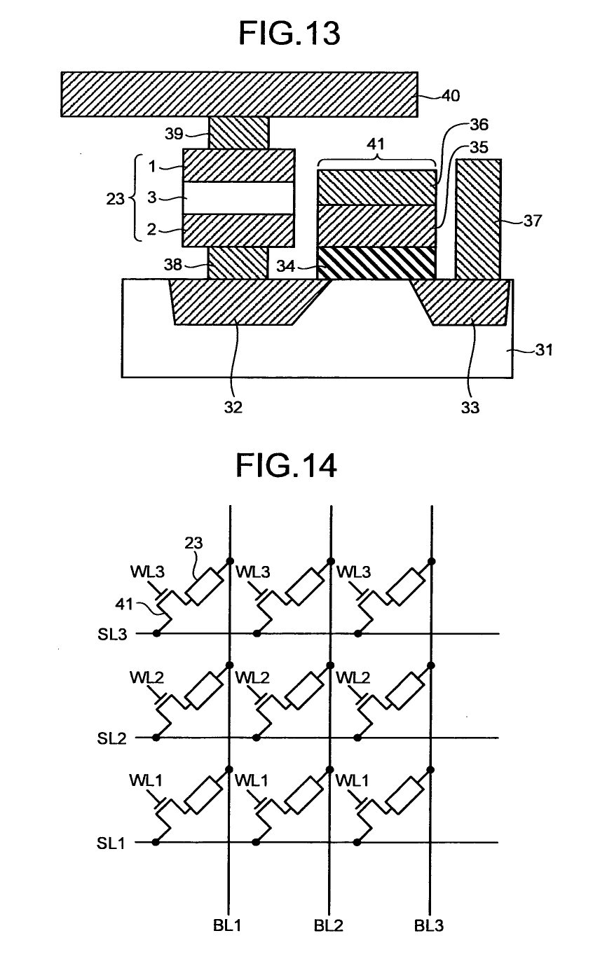

FIG. 13 is a sectional view of a schematic configuration of a nonvolatile variable resistance element according to a sixth embodiment.

In FIG. 13, a gate electrode 35 is formed on the semiconductor substrate 31 via a gate insulating film 34. A word line 36 is formed on the gate electrode 35. diffusion layers 32 and 33 are formed on the semiconductor substrate 31 across a channel region formed under the gate electrode 35, whereby a transistor 41 is formed. A source line 37 is connected to the impurity diffusion layer 33.

A nonvolatile variable resistance element 23 is arranged on the semiconductor substrate 31 to be adjacent to the transistor 41. As the nonvolatile variable resistance element 23, for example, a configuration same as that shown in FIG. 1 can be used. The second electrode 2 of the nonvolatile variable resistance element 23 is connected to the diffusion layer 32 via a connection conductor 38. The first electrode 1 of the nonvolatile variable resistance element 23 is connected to a bit line 40 via a connection conductor 39.

The transistor 41 is turned on via the word line 36, whereby the nonvolatile variable resistance element 23 can be accessed and the nonvolatile variable resistance element 23 as a reading and writing target can be selected.

In the explanation of an example shown in FIG. 13, the configuration shown in FIG. 1 is used. Besides, the configuration shown in FIG. 6 can be used.

FIG. 14 is a plan view of a schematic configuration of a memory cell array to which the nonvolatile variable resistance element shown in FIG. 13 is applied.

In FIG. 14, bit lines BL1 to BL3 are wired in a column direction and word lines WL1 to WL3 are wired in a row direction on the semiconductor substrate 31 shown in FIG. 13. Nonvolatile variable resistance elements 23 and transistors 41 are arranged in cross-point sections of the respective bit lines BL1 to BL3 and the respective word lines WL1 to WL3. The nonvolatile variable resistance elements 23 and the transistors 41 are connected in series to each other.

One ends of the nonvolatile variable resistance elements 23 in the same columns are connected to the same bit lines BL1 to BL3. One ends of the transistors 41 in the same rows are connected to the same source lines SL1 to SL3. Gate electrodes 35 of the transistors 41 in the same rows are connected to the same word lines WL1 to WL3.

The transistors 41 are turned on via the word lines WL1 to WL3, whereby a voltage can be applied between first electrodes 1 and second electrodes 2 of the nonvolatile variable resistance elements 23 in a selected row. Therefore, it is possible to prevent an electric current from flowing to the nonvolatile variable resistance elements 23 in an unselected rows during readout from the nonvolatile variable resistance elements 23 in the selected row. It is possible to reduce a readout time.

### Seventh Embodiment

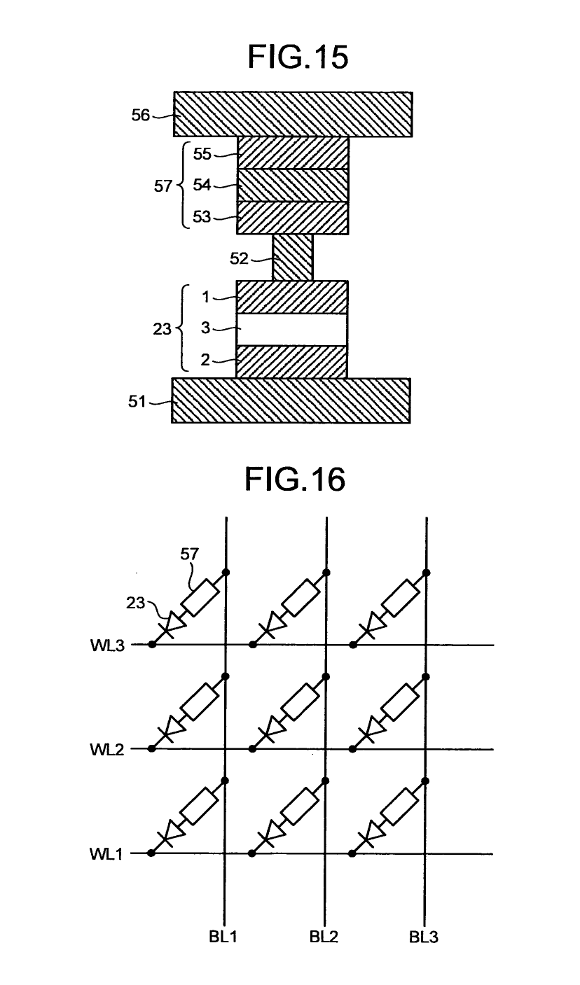

FIG. 15 is a sectional view of a schematic configuration of a nonvolatile variable resistance element according to a seventh embodiment.

In FIG. 15, the nonvolatile variable resistance element 23 is arranged on a lower wire 51. A unipolar variable resistance element 57 is arranged on the nonvolatile variable resistance element 23 via a connection conductor 52. An upper wire 56 is arranged on the unipolar variable resistance element 57. In the unipolar variable resistance element 57, a variable resistance layer 54 is stacked on a lower electrode 53 and an upper electrode is stacked on the variable resistance layer 54. As the variable resistance layer 53, transition metal oxide such as HfO₂, ZrO₂, NiO, V₂O₅, ZnO, TiO₂, Nb₂O₅, WO₃, or CoO can be used. In this unipolar variable resistance element 57, it is possible to change the resistance of the variable resistance layer 54 by changing the amplitude and the time of pulse stress applied to the variable resistance layer 54.

When forward bias is applied to the unipolar variable resistance element 57, it is possible to form the metal filaments 11 shown in FIG. 3A in the variable resistance layer 3 and reduce the resistance of the nonvolatile variable resistance element 23 by applying the set voltage Vset to the nonvolatile variable resistance element 23 via the lower wire 51.

On the other hand, when reverse bias is applied to the unipolar variable resistance element 57, it is possible to eliminate the metal filaments 11 shown in FIG. 3A from the variable resistance layer 3 and increase the resistance of the nonvolatile variable resistance element 23 by applying the reset voltage Vreset to the nonvolatile variable resistance element 23 via the lower wire 51.

It is possible to achieve a high ON/OFF ratio by connecting the nonvolatile variable resistance element 23 in series to the unipolar variable resistance element 57 compared with an ON/OFF ratio achieved by connecting a diode in series to the unipolar variable resistance element 57.

In the explanation of an example shown in FIG. 15, the configuration shown in FIG. 1 is used as the nonvolatile variable resistance element 23. Besides, the configuration shown in FIG. 6 can be used.

FIG. 16 is a plan view of a schematic configuration of a memory cell array to which the nonvolatile variable resistance element shown in FIG. 15 is applied.

In FIG. 16, the bit lines BL1 to BL3 are wired in a column direction and the word lines WL1 to WL3 are wired in a row direction. The nonvolatile variable resistance elements 23 and the unipolar variable resistance elements 57 are arranged in cross-point sections of the respective bit lines BL1 to BL3 and the respective word lines WL1 to WL3. The nonvolatile variable resistance elements 23 and the unipolar variable resistance elements 57 are connected in series to each other.

One ends of the unipolar variable resistance elements 57 in the same columns are connected to the same bit lines BL1 to BL3. One ends of the nonvolatile variable resistance elements 23 in the same rows are connected to the same word lines WL1 to WL3.

By connecting the nonvolatile variable resistance elements 23 and the unipolar variable resistance elements 57 in this way, the resistance of the variable resistance elements is increased when reverse bias is applied to an unselected cell. Therefore, it is possible to reduce current noise flowing from the unselected cell during current readout from a selected cell, improve stability of a readout operation, and reduce a readout time.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A nonvolatile variable resistance element, comprising:
a first electrode;
a second electrode; and
a variable resistance layer arranged between the first electrode and the second electrode and comprising a polycrystalline semiconductor,
wherein
the polycrystalline semiconductor is polysilicon,
the first electrode is impurity doped silicon, and
the second electrode comprises at least one metal selected from the group consisting of Ag, Ti, Ni, Co, Al, Cr, Cu, W, Hf, Ta, and Zr.

2. The nonvolatile variable resistance element according to claim 1, wherein the variable resistance layer changes from a high-resistance state to a low-resistance state when metal filaments become bigger along grain boundaries of the polycrystalline semiconductor, and changes from the low-resistance state to the high-resistance state when the metal filaments formed along the grain boundaries of the polycrystalline semiconductor become smaller.

3. The nonvolatile variable resistance element according to claim 2, wherein the second electrode comprises a metal element that forms the metal filaments.

4. The nonvolatile variable resistance element according to claim 3, wherein the metal filaments become bigger in the variable resistance layer when the metal element is supplied from the second electrode to the variable resistance layer, and the metal filaments become smaller in the variable resistance layer when the metal element is collected from the variable resistance layer to the second electrode.

5. The nonvolatile variable resistance element according to claim 2, wherein the metal filaments are formed in the variable resistance layer when a set voltage is applied to the second electrode, and the metal filaments are eliminated from the variable resistance layer when a reset voltage is applied to the second electrode.

6. (canceled)

7. The nonvolatile variable resistance element according to claim 1, wherein the polycrystalline semiconductor has a hydrogen concentration of 10¹⁹ cm⁻³ or higher.

8. The nonvolatile variable resistance element according to claim 1, wherein the polycrystalline semiconductor comprises oxygen.

9. The nonvolatile variable resistance element according to claim 1, wherein the polycrystalline semiconductor comprises OH groups in grain boundaries.

10. The nonvolatile variable resistance element according to claim 1, wherein a grain diameter of the polycrystalline semiconductor is in a range of 2 nanometers to 5 nanometers.

11. A nonvolatile variable resistance element comprising:
a first electrode;
a second electrode; and
a variable resistance layer arranged between the first electrode and the second electrode, metal filaments being reversibly formed along grain boundaries of a polycrystalline semiconductor in the variable resistance layer,
wherein
the polycrystalline semiconductor is polysilicon,
the first electrode is impurity doped silicon, and
the second electrode comprises at least one metal selected from the group consisting of Ag, Ti, Ni, Co, Al, Cr, Cu, W, Hf, Ta, and Zr.

12. The nonvolatile variable resistance element according to claim 11, wherein the second electrode comprises a metal element that forms the metal filaments.

13. The nonvolatile variable resistance element according to claim 12, wherein the metal filaments become bigger in the variable resistance layer when the metal element is supplied from the second electrode to the variable resistance layer, and the metal filaments become smaller in the variable resistance layer when the metal element is collected from the variable resistance layer to the second electrode.

14. (canceled)

15. The nonvolatile variable resistance element according to claim 11, wherein the polycrystalline semiconductor has a hydrogen concentration of 10¹⁹ cm ⁻³ or higher.

16. The nonvolatile variable resistance element according to claim 11, wherein the polycrystalline semiconductor comprises oxygen.

17-20. (canceled)

21. A nonvolatile variable resistance element, comprising:
a first electrode;
a second electrode; and
a variable resistance layer arranged between the first electrode and the second electrode and comprising a polycrystalline semiconductor, wherein the polycrystalline semiconductor comprises oxygen.

22. The nonvolatile variable resistance element according to claim 21, wherein the polycrystalline semiconductor has a hydrogen concentration of 10¹⁹ cm⁻³ or higher.

23. The nonvolatile variable resistance element according to claim 21, wherein the polycrystalline semiconductor comprises OH groups in grain boundaries.

24. The nonvolatile variable resistance element according to claim 21, wherein a grain diameter of the polycrystalline semiconductor is in a range of 2 nanometers to 5 nanometers.
